(19) United States
(12) Patent Application Publication
(10) Pub. No.: US 2017/0370020 A1
(43) Pub. Date: Dec. 28, 2017

(54) METHOD FOR PREPARING RESTART OF REACTOR FOR EPITAXIAL GROWTH ON WAFER

(71) Applicant: LG SILTRON INC., Gumi-si, Gyeongsangbuk-do (KR)

(72) Inventors: Dong-Ho KANG, Gumi-si (KR); Man-Kee CHO, Gumi-si (KR)

(21) Appl. No.: 15/544,825

(22) PCT Filed: Dec. 23, 2015
(86) PCT No.: PCT/KR2015/014216

§ 371 Date: Jul. 19, 2017

(30) Foreign Application Priority Data
Jan. 22, 2015 (KR) 10-2015-0010803

(51) Int. Cl. C30B 25/10; C30B 25/14; H01L 21/02

(52) U.S. Cl. CPC C30B 25/10; C30B 25/14; H01L 21/0262

(57) ABSTRACT

Provided is a process of baking the inside of a reaction chamber in a re-operation preparation process of the reaction chamber in which epitaxial growth is performed on a wafer. The process of baking the inside of the reaction chamber in the re-operation preparation process of the reaction chamber in which epitaxial growth is performed on the wafer includes rising an inner temperature of the reaction chamber in stages according to a time and introducing a hydrogen gas to upper and lower sides of a susceptor through a main valve and a slit valve, which are provided in a side surface of the reaction chamber. Thus, since power of a heating source for transmitting heat into the reaction chamber increases in stages, an atmosphere in the reaction chamber may be unstable to allow stagnant moisture and contaminants to flow, thereby effectively discharging the moisture and contaminants.

### TECHNICAL FIELD

The present disclosure relates to a re-operation preparation process in a chamber, and more particularly, to a re-operation preparation method for performing an epitaxial growth process for manufacturing a following epitaxial wafer by removing moisture and impurities remaining in a chamber after growth of an epitaxial wafer is finished.

### BACKGROUND ART

Conventional silicon wafers may be manufactured by performing a single crystal growth process, a slicing process, a grinding process, a wrapping process, a polishing process, and a cleaning process for removing an abrasive or foreign substances that are attached to the wafers after the wafers are polished. Such a wafer manufactured through the above-described processes may be called a polished wafer, and a wafer that is manufactured by growing another single crystal layer (an epitaxial layer) on the polished wafer may be called an epitaxial wafer.

The epitaxial wafer may have properties in which defects are fewer than those of the polished wafer, and a concentration and kind of impurities are controllable. Also, the epitaxial layer may be advantageous to improve yield of a semiconductor device and device characteristics due to high purity and superior crystal properties thereof. Chemical vapor deposition may be a process for growing a material on an object such as a semiconductor wafer to form a thin layer. Thus, the layer having conductivity may be deposited on the wafer so that the wafer has desired electrical characteristics.

A chemical vapor deposition device for depositing an epitaxial layer on a surface of a wafer includes a process chamber in which the deposition of the epitaxial layer is performed, a susceptor mounted therein, a heating lamp disposed on upper and lower portions of the process chamber, and a gas injection unit for injecting a source gas onto the wafer. The source gas injected through the gas injection unit may be injected onto the wafer placed on the susceptor to form an epitaxial layer.

When an epitaxial process that is performed at a high temperature is completed in a chamber of an epitaxial reactor for growing the epitaxial layer on the wafer, moisture containing metal impurities may exist in the chamber. When the impurities exist in the chamber, it may be difficult to manufacture an epitaxial wafer having high quality. Thus, when the process for manufacturing the epitaxial water is completed, the impurities remaining in the chamber have to be removed to form an atmosphere under which the epitaxial process is performed again.

Thus, to re-operate the epitaxial reactor, a nitrogen gas is injected into the chamber having room temperature for three hours to ventilate the impurity particles within the chamber. Then, while the inside of the chamber is maintained to a high temperature for a predetermined time after the inner temperature of the chamber increases, a baking process using a hydrogen gas is performed to remove the remaining moisture or impurities.

However, since a baking process that is performed after the inside of the chamber is raised in temperature is performed at a predetermined temperature, the moisture and various contaminants remaining in the epitaxial reactor are thermally stabilized. Thus, it is difficult to remove the contaminants. Also, even though the moisture and contaminants are removed by injecting a hydrogen gas, residue moisture and metal contaminants may exist in the epitaxial reactor as ever. As a result, it may be difficult to secure quality of an epitaxial wafer that is manufactured under this condition.

### DISCLOSURE

### Technical Problem

Embodiments provides a method in which a temperature is changed in stages during a baking process that is performed at a high temperature to activate a flow of stagnant contaminants, thereby discharging the moisture and contaminants to the outside of a process chamber and reducing a re-operation time of a reactor in a re-operation preparation process of the reactor for manufacturing an epitaxial wafer.

### Technical Solution

In one embodiment, a process of baking the inside of a reaction chamber in a re-operation preparation process of the reaction chamber in which epitaxial growth is performed on a wafer includes: rising an inner temperature of the reaction chamber in stages according to a time; and introducing a hydrogen gas to upper and lower sides of a susceptor through a main valve and a slit valve, which are provided in a side surface of the reaction chamber.

The rising of the inner temperature of the reaction chamber in stages according to the time may include setting power of a heating source for applying heat to the reaction chamber to increase in stages according to the time, and the rising of the inner temperature of the reaction chamber in stages according to the time and the introducing of the hydrogen gas to the upper and lower sides of the susceptor may be performed at the same time.

### Advantageous Effect

According to the embodiment, since the moisture and contaminants stagnant in the reaction chamber are quickly removed, the time taken to reach the minimum value of the MCLT for performing the re-operation of the epitaxial reactor may be reduced. Therefore, the preparation time taken to perform the re-operation of the reactor may be reduced to improve the production yield of the epitaxial wafer.

### DESCRIPTION OF DRAWING

FIG. 1 is a view of an epitaxial reactor according to an embodiment.

FIG. 2 is a view of the susceptor in an epitaxial growth apparatus when viewed from an upper side.

FIG. 3 is a graph illustrating a power value of a heating source, which rises a temperature of the epitaxial reactor according to an embodiment.

FIG. 4 is a graph illustrating a minority carrier life time (MCLT) level in the reaction chambers in the process for preparing the epitaxial reactor according to the related art and the embodiment.

### MODE FOR INVENTION

Although embodiments are described in detail with reference to the accompanying drawings, the present disclosure is not limited to the embodiments. Moreover, detailed descriptions related to well-known functions or configurations will be ruled out in order not to unnecessarily obscure subject matters of the present disclosure.

Embodiments provide to change an inner state of a reaction chamber by changing process conditions in an epitaxial reactor (a reaction chamber) so that moisture and contaminants stagnant in the epitaxial reactor become an unstable state.

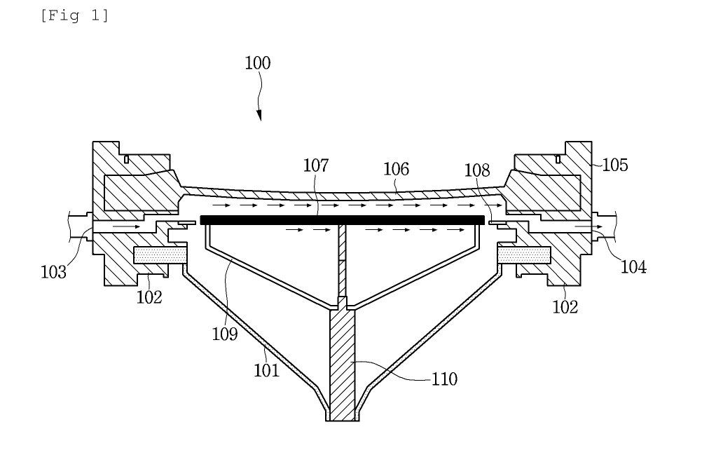

FIG. 1 is a view of an epitaxial growth apparatus, i.e., a cross-sectional view illustrating an initial position of a susceptor when a baking process is performed in a process chamber.

Referring to FIG. 1, an epitaxial growth apparatus 100 may include upper and lower liners 105 and 102, an upper cover 106, a lower cover 101, a susceptor 107, a preheating ring 108, a susceptor support 109, a gas supply port 103, a gas discharge port 104, and a main shaft 110.

The gas supply port 103 connected to a gas supply line may be disposed on one side of the epitaxial growth apparatus 100, and the gas discharge port 104 connected to a gas discharge line may be disposed on the other side of the epitaxial growth apparatus 100. Also, the epitaxial growth apparatus 100 may include the lower cover 101 and the upper cover 106.

The lower liner 102 may be disposed to surround the susceptor 107, and the upper liner 105 may be disposed to face an upper portion of the lower liner 102. The preheating ring 108 may have a ring shape along an inner surface of the lower liner 102 that is adjacent to the susceptor 107 and be seated on the lower liner 102. Also, the preheating ring 108 may be disposed to surround the susceptor 107 so that a gas supplied onto a wafer has a uniform temperature.

The susceptor 107 may be a portion on which the wafer is mounted during epitaxial reaction. The susceptor 107 may be provided as a plate formed of a material such as carbon graphite and silicon carbide. The susceptor 107 may be supported by the main shaft 110 that is disposed on a lower portion thereof and the susceptor support 109 that is branched into several parts in an edge direction of the susceptor 107. As illustrated in FIG. 1, the epitaxial process may be performed in a state in which the susceptor 107 is fixed at the same height as the preheating ring 108.

To manufacturing the epitaxial wafer, an epitaxial layer is vapor-grown under a high temperature in the reaction chamber. Thus, if metal impurities or remaining moisture exist in the reaction chamber when the epitaxial layer is grown, the manufactured epitaxial wafer may be contaminated by the metal impurities, and thus, it may be difficult to ensure quality of the epitaxial wafer.

Thus, a preventive maintenance (PM) may be performed in the reaction chamber after the various processes are performed. Here, after the PM is performed, the remaining moisture may be generated in the reaction chamber. To solve this limitation, a re-operation preparation process for the epitaxial growth apparatus may be performed. The re-operation preparation process may include a process of injecting a nitrogen gas into the chamber having room temperature for three hours to ventilate impurity particles in the reaction chamber, a process of rising the inside of the reaction chamber to a predetermined temperature, a process of performing the baking process using the hydrogen gas while maintaining the reaction chamber having the raised temperature to a high temperature for a predetermined time, a process of confirming whether a dopant exists in the reaction chamber, and a process of removing a metal contamination source remaining in the reaction chamber.

Embodiments may be performed in the baking process that is performed in the reaction chamber having the raised temperature among the above-described processes.

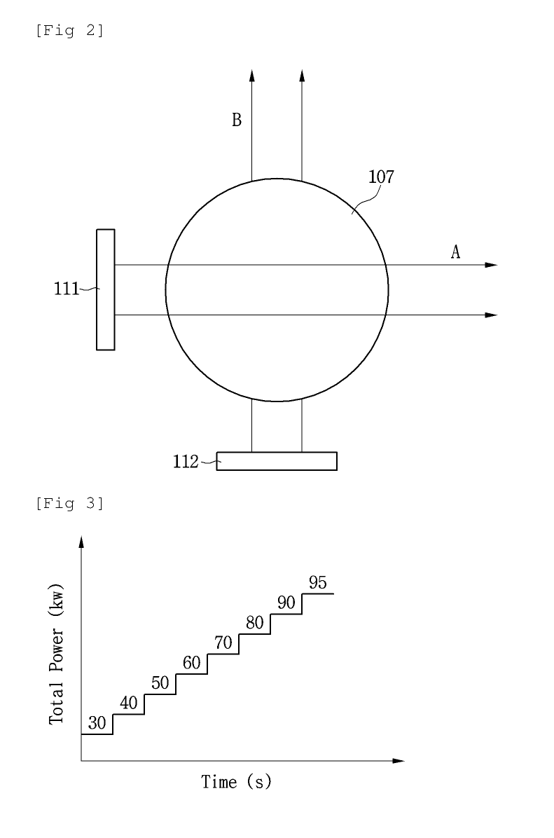

FIG. 2 is a view of the susceptor in the epitaxial growth apparatus when viewed from an upper side.

Referring to FIG. 2, a main valve 111 is disposed above the susceptor 107 in a gas inflow direction in which a reaction gas is introduced, and the hydrogen gas that is a carrier gas for moving a reaction gas and moving the impurities generated during the process is introduced through the main valve 111. The introduced hydrogen gas may flow on a top surface of the susceptor in a direction A that is a direction in which the gas is discharged.

Also, a slit valve 112 is disposed below the susceptor 107 in a direction that is perpendicular to the main valve 111, and the hydrogen gas that is the carrier gas for moving the reaction gas and moving the impurities generated during the process may be introduced. The hydrogen gas introduced through the slit valve 112 may flow to a lower side of the susceptor 107. However, the hydrogen gas may flow in a direction B, but substantially flow to be one-sided in the direction A by suction force of a gas discharge hole.

That is, the hydrogen gas introduced through the main valve may flow in a space between the top surface of the susceptor 107 and the upper cover 106 in a direction of a gas discharge hole. The hydrogen gas introduced through the slit valve moves from the lower side of the susceptor to the gas discharge hole. Particularly, in the process for preparing the re-operation of the epitaxial growth apparatus 100, the susceptor 107 may be disposed at the same height as the preheating ring 108. Here, the hydrogen gas may be introduced at a flow rate of about 90 slm through the main valve and at a flow rate of about 20 slm through the slit valve.

The re-operation process for the epitaxial growth apparatus 100 may be performed under the above-described conditions. For the baking process that is performed after the inside of the reaction chamber is raised in temperature, an inner temperature of the reaction chamber may be raised up to a predetermined temperature. Here, if the temperature is linearly raised, the moisture and various contaminants remaining in the epitaxial reactor may be thermally stabilized.

In an embodiment, to form an unstable thermal state in the reaction chamber in the baking process during the re-operation process of the reactor, the inner temperature of the reaction chamber may be nonlinearly raised, for example, be raised in stages. In an embodiment, a time-variable temperature of the reaction chamber may be different according to time periods. Thus, power of the heating source for applying heat to the reaction chamber may vary in increase range according to a time.

In an embodiment, since the power of the heating source for applying the heat to the inside of the reaction chamber increases in stages to change the inner temperature of the reaction chamber. Here, a process of introducing the hydrogen gas to upper and lower sides of the susceptor may be performed.

In the process of rising the temperature of the reaction chamber, the inside of the reaction chamber may be thermally unstable. Thus, since the hydrogen gas is injected into the reaction chamber through the main valve and the slit valve, the moisture and the contaminants within the reaction chamber may be more effectively discharged by the flow of the hydrogen gas.

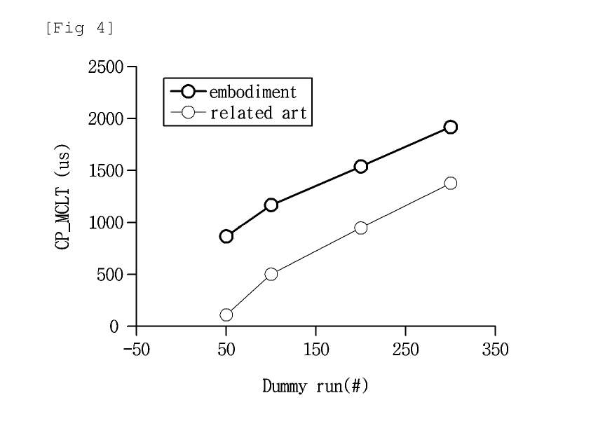

FIG. 3 is a graph illustrating a power value of the heating source, which rises a temperature of the epitaxial reactor according to an embodiment. Referring to FIG. 3, a time-variable power value of the heating source, which rises the temperature of the reaction chamber is illustrated. In an embodiment, a value of power applied to the reaction chamber according to a time may increase in stages in the process of baking the inside of the reaction chamber.

Particularly, the power of the heating source may be set to successively increase from about 30 kw to about 95 kw. Here, an increase range in each stage may be set to power of about 10 kw. For example, heat may be applied to the reaction chamber at power of about 30 kw for a predetermined time, and then, heat may be applied to the reaction chamber at power of about 40 kw for a predetermined time so that the power value successively increases up to about 95 kw. A reflector of the reaction chamber applied to the embodiment may be melted if the power of the heating source increases to about 95 kw. Thus, the power may be set to increase up to about 95 kw.

As the power of the heating source increases in stages, the inner temperature of the reaction chamber may be raised up to a temperature of about 600° C. to about 1,200° C. When the power of the heating source is uniform, the inner temperature of the reaction chamber may be linearly changed. Like the embodiment, when the power of the heating source increases in stages, the inner temperature of the reaction chamber may be nonlinearly changed.

As described above, the power of the heating source may gradually increase according to an increase of a time. Here, the power may be set to be different in each stage. As a result, the inside of the reaction chamber may be thermally unstable, and thus, kinetic energy of the moisture and the particles containing the contaminants, which exist in the reaction chamber may increase. In an embodiment, in the process of baking the inside of the reaction chamber in the process of preparing the epitaxial reactor, a process in which the power of the heating source, which rises the inner temperature of the reaction chamber increases in stages may be repeatedly performed several times. Preferably, the process may be performed two times to five times according to efficiency of the baking process.

In an embodiment, the process in which the power of the hating source, which rises the inner temperature of the reaction chamber, is set in stages according to a time and a process in which the hydrogen gas is introduced into the upper and lower sides of the susceptor through the main valve and the slit valve may be performed at the same time.

Thus, since the moisture and the contaminants remaining in the reaction chamber move by the hydrogen gas that is a carrier gas introduced through the main valve and the slit valve to flow along the upper and lower sides of the susceptor, possibility of discharge of the moisture and the contaminants to the outside of the reaction chamber may increase due to the movement of the hydrogen gas.

FIG. 4 is a graph illustrating a minority carrier life time (MCLT) level in the reaction chambers in the process for preparing the epitaxial reactor according to the related art and the embodiment.

The MCLT may become one measure for determining whether the re-operation of the epitaxial growth apparatus is completely prepared. The MCLT may denote a mean time taken to recombine excessive minority electrons. The more an amount of impurities in the reaction chamber increases, the more the MCLT decreases. In general, in the re-operation preparation process for the epitaxial growth apparatus, various processes of the re-operation preparation process may be performed until the MCLT reaches a predetermined value.

In the graph of FIG. 4, a horizontal axis denotes the number of dummy run of the epitaxial wafer, and a vertical axis denotes a MCLT value. In the method in which the power of the heating source, which rises the inner temperature of the reaction chamber according to the related art, is linearly changed according to the time, when the number of dummy run is 50, the MCLT may be about 50 ms. However, in the reaction chamber to which the method according to the embodiment is applied, when the number of dummy run is about 50, the MCLT may be about 446 ms. Thus, it is seen that a different in MCLT according to the related art and the embodiment is over about 900 ms when the number of dummy run increases to about 300.

That is, as the number of dummy run increases, the MCLT may significantly increase in the method for re-operating the epitaxial growth apparatus according to an embodiment. Thus, it is seen to more quickly reach requirements for re-operating the epitaxial growth apparatus.

As described above, in the method for preparing the reactor for manufacturing the epitaxial wafer according to the embodiment, the power of the heating source for transmitting heat into the reaction chamber may increase in stages in the process of baking the inside of the reaction chamber after the PM process to form the unstable state in the reaction chamber and allow the stagnant moisture and contaminants to flow, thereby effectively discharging the moisture and contaminants along the flow of the hydrogen gas.

Also, since the moisture and contaminants stagnant in the reaction chamber are quickly removed, the time taken to reach the minimum value of the MCLT for performing the re-operation of the epitaxial reactor may be reduced. Therefore, the preparation time taken to perform the re-operation of the reactor may be reduced to improve the production yield of the epitaxial wafer.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

Since the embodiment is applied to the epitaxial growth apparatus for growing the epitaxial layer on the wafer, the industrial applicability is high.

1. A method for preparing a re-operation of an epitaxial growth apparatus as a process of baking the inside of a reaction chamber in a re-operation preparation process of the reaction chamber in which epitaxial growth is performed on a wafer, the method comprising:
rising an inner temperature of the reaction chamber in stages according to a time; and
introducing a hydrogen gas to upper and lower sides of a susceptor through a main valve and a slit valve, which are provided in a side surface of the reaction chamber.

2. The method according to claim 1, wherein the rising of the inner temperature of the reaction chamber in stages according to the time comprises setting power of a heating source for applying heat to the reaction chamber to increase in stages according to the time.

3. The method according to claim 1, wherein the rising of the inner temperature of the reaction chamber in stages according to the time and the introducing of the hydrogen gas to the upper and lower sides of the susceptor are performed at the same time.

4. The method according to claim 2, wherein the power of the heating source is set to have a range of about 30 kw to about 95 kw.

5. The method according to claim 4, wherein the power of the heating source increases by 10 kw per each time period in the range of about 30 kw to about 95 kw.

6. The method according to claim 1, wherein, in the process of baking the inside of the reaction chamber, the inner temperature of the reaction chamber is nonlinearly raised up to a temperature of about 600° C. to about 1,200° C.

7. The method according to claim 1, wherein the hydrogen gas introduced through the main valve has a flow rate of about 90 slm, and the hydrogen gas introduced through the slit valve has a flow rate of about 20 slm.

8. The method according to claim 1, wherein, in the process of baking the inside of the reaction chamber, the rising of the inner temperature of the reaction chamber in stages according to the time is repeatedly performed several times.

9. The method according to claim 8, wherein the rising of the inner temperature of the reaction chamber in stages according to the time is performed two times to five times in the process of baking the inside of the reaction chamber.

10. The method according to claim 1, wherein, in the rising of the inner temperature of the reaction chamber in stages according to the time, a variation in inner temperature of the reaction chamber according to the time is set to be different in each stage.

11. The method according to claim 10, wherein the rising of the inner temperature of the reaction chamber in stages according to the time is set so that an increase range of a power value of the heating source according to the time is set to be different in each stage.
